(19) United States
(12) Patent Application Publication
(10) Pub. No.: US 2026/0362651 A1
(43) Pub. Date: Nov. 12, 2026

(54) CONNECTOR, LIQUID COOLING SYSTEM, CABINET, AND SERVER

(71) Applicant: DOUYIN VISION CO., LTD., Beijing (CN)

(72) Inventors: Shiqiang Li, Beijing (CN); Jian Wang, Beijing (CN)

(21) Appl. No.: 19/713,947

(22) Filed: Jun. 19, 2026

(30) Foreign Application Priority Data
Sep. 9, 2025 (CN) 202511287543.0

(51) Int. Cl. H05K 7/20; F16L 25/00

(52) U.S. Cl. CPC H05K 7/20772; F16L 25/00

(57) ABSTRACT

A connector, a liquid cooling system, a cabinet, and a server are provided. The connector includes a rotating member, a base, and a connection pipe. The rotating member includes a limiting through hole. The base includes a limiting groove, a first through hole, and a second through hole. The first through hole is provided at one end of the limiting groove and communicates with the limiting groove. The second through hole is provided at the other end of the limiting groove and communicates with the limiting groove. The limiting groove surrounds the rotating member. An inner diameter of the first/second through hole at a position connected to the limiting groove is smaller than an outer diameter of the rotating member. The connection pipe passes through the limiting through hole, the first through hole, and the second through hole and is connected to the rotating member.

### TECHNICAL FIELD

Embodiments of the present disclosure generally relate to the field of electrical equipment, and in particular, to a connector, a liquid cooling system, a cabinet, and a server.

### BACKGROUND

A liquid cooling system may be used in a server to ensure efficient operation of a heat generating unit. In some cabinet-type servers, when the heat generating unit needs to be installed or maintained, an operator may insert a support member, on which the heat generating unit and a connector are installed, into a server cabinet, and connect the connector to another connector of a liquid cooling pipeline in the cabinet. When the liquid cooling system is operating, a cooling medium may circulate between the connector and the liquid cooling pipeline, thereby taking away heat generated when the heat generating unit is working, and helping to maintain the efficient operation of the heat generating unit and even the entire server.

### SUMMARY

In a first aspect of the present disclosure, a connector is provided. The connector includes: a rotating member including a limiting through hole; a base including a limiting groove, a first through hole, and a second through hole that are respectively provided around a first axis, the first through hole being provided at one end of the limiting groove along the first axis and communicating with the limiting groove, the second through hole being provided at the other end of the limiting groove along the first axis and communicating with the limiting groove, the limiting groove surrounding the rotating member, and an inner diameter of the first through hole and an inner diameter of the second through hole at a position connected to the limiting groove being smaller than an outer diameter of the rotating member, to limit the rotating member in the limiting groove and allow the rotating member to rotate relative to the limiting groove about the first axis and an axis perpendicular to the first axis; and a connection pipe passing through the limiting through hole, the first through hole, and the second through hole and being connected to the rotating member, to move with the rotating member relative to the base.

In a second aspect of the present disclosure, a liquid cooling system is provided. The liquid cooling system includes: a liquid inlet pipe; a liquid outlet pipe; a pair of auxiliary connectors respectively communicating with the liquid inlet pipe and the liquid outlet pipe; a heat exchange unit including an inlet and an outlet; and a pair of connectors according to the first aspect of the present disclosure, respectively communicating with the inlet and the outlet of the heat exchange unit, and respectively detachably connected to a corresponding auxiliary connector of the pair of auxiliary connectors.

In a third aspect of the present disclosure, a cabinet is provided. The cabinet includes: a cabinet body; a support member detachably connected to the cabinet body; and the liquid cooling system according to the second aspect of the present disclosure, the liquid inlet pipe, the liquid outlet pipe, and the pair of auxiliary connectors being provided in the cabinet body, and the heat exchange unit and the pair of connectors being connected to the support member.

In a fourth aspect of the present disclosure, a server is provided. The server includes the cabinet according to the third aspect of the present disclosure.

It should be understood that the content described in this section is not intended to identify key or essential features of the embodiments of the present disclosure, nor is it intended to limit the scope of the present disclosure. Other features of the present disclosure will be readily envisaged through the following description.

### BRIEF DESCRIPTION OF THE DRAWINGS

The foregoing and other features, advantages, and aspects of the embodiments of the present disclosure become more apparent with reference to the following detailed description and in conjunction with the drawings. In the drawings, the same or similar reference numerals denote the same or similar elements.

FIG. 1 is a perspective view of a connector according to some embodiments of the present disclosure;

FIG. 2 is an exploded view of the connector according to some embodiments of the present disclosure, showing a first annular limiting groove;

FIG. 3 is a schematic diagram of an internal structure of the connector according to some embodiments of the present disclosure;

FIG. 4 is a cross-sectional view of the connector according to some embodiments of the present disclosure, showing that a central axis of a connection pipe is aligned with a first axis;

FIG. 5 is a cross-sectional view of the connector according to some embodiments of the present disclosure, showing that the connection pipe is in a deflected state;

FIG. 6 is a top view of the connector and a support member according to some embodiments of the present disclosure, showing that the central axis of the connection pipe is aligned with the first axis;

FIG. 7 is a top view of the connector and the support member according to some embodiments of the present disclosure, showing that the connection pipe is in the deflected state;

FIG. 8 is a perspective view of a cabinet according to some embodiments of the present disclosure, showing a support member separated from a cabinet body;

FIG. 9 is a perspective view of the cabinet according to some embodiments of the present disclosure, showing the support member partially inserted into the cabinet body;

FIG. 10 is a perspective view of the cabinet according to some embodiments of the present disclosure, showing the support member fully inserted into the cabinet body; and

FIG. 11 is a schematic diagram of an internal structure of the cabinet according to some embodiments of the present disclosure, showing the support member fully inserted into the cabinet body.

### REFERENCE CHARACTER LIST

R1: first axis; R2: second axis; R3: third axis;
X: first direction; Y: second direction; Z: third direction;
100: connector;
10: rotating member; 11: first bearing surface; 111: first annular limiting groove; 12: second bearing surface; 13: limiting through hole;
20: base; 21: first portion; 210: first through hole; 22: second portion; 220: second through hole; 23: limiting groove;
30: connection pipe; 31: pipe body; 32: quick connector;
40: conical spring assembly; 41: first conical spring; 42: second conical spring; 401: inner connecting portion; 402: outer connecting portion;
51: first support ring; 511: first groove; 52: second support ring; 521: second groove; 53: third support ring; 531: second annular limiting groove; 54: first ball; 55: second ball;
60: elastic assembly;
801: liquid inlet pipe; 802: liquid outlet pipe; 803: auxiliary connector; 804: heat exchange unit;
901: cabinet body; 902: support member.

### DETAILED DESCRIPTION OF EMBODIMENTS

Preferred embodiments of the present disclosure will be described in more detail below with reference to the drawings. Although the preferred embodiments of the present disclosure are shown in the drawings, it should be understood that the present disclosure may be implemented in various forms and should not be limited to the embodiments set forth herein. Instead, these embodiments are provided for a thorough and complete understanding of the present disclosure, and the scope of the present disclosure may be fully conveyed to those skilled in the art.

The term “include/comprise” and the variations thereof used herein mean open-ended inclusion, that is, “include/comprise but not limited to”. Unless otherwise stated, the term “or” means “and/or”. The term “based on” means “based at least partially on”. The terms “an example embodiment” and “an embodiment” mean “at least one example embodiment”. The term “other embodiment” means “at least one other embodiment”. The terms “first”, “second”, and the like may refer to different or same objects.

In some server cabinets, in a cabinet-level liquid cooling blind-mating system, due to a long size chain of a cabinet structure, system-level tolerance accumulation makes it difficult to align male and female blind-mating connectors, and thus a blind-mating floating mechanism is required to assist in completing the mating. In the mating process, a lateral force may be generated in a guiding and correcting stage. After the mating is completed, there may be a continuous lateral fitting stress between the connectors that fit with each other. The lateral fitting stress not only affects the reliability of the connectors in the plugging and unplugging process, but also affects the sealing performance between the connectors, and there is a risk of coolant leakage or splashing during the use.

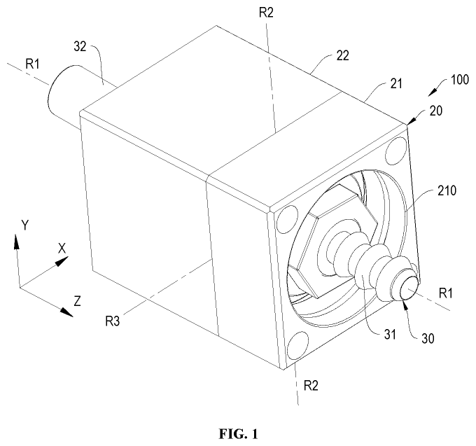

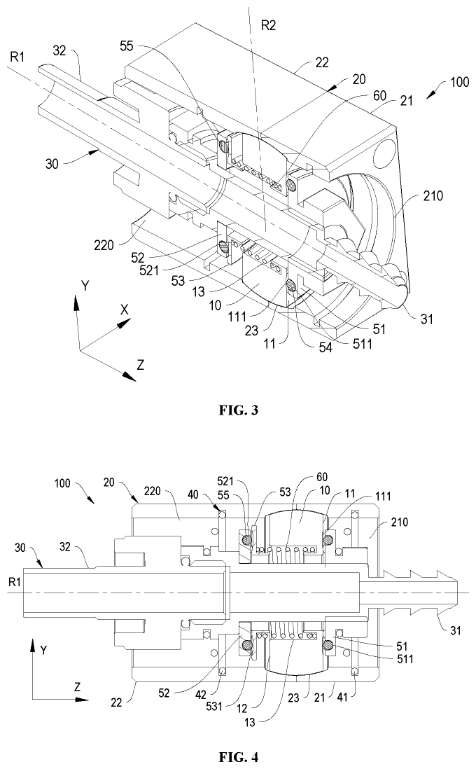

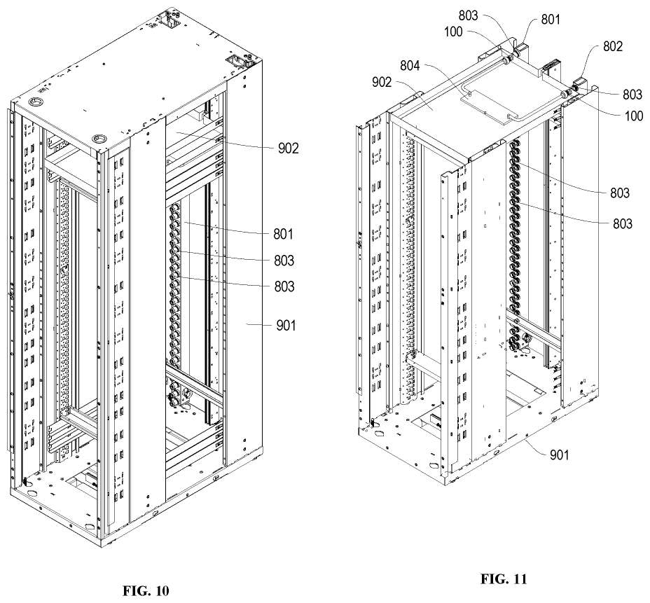

Embodiments of the present disclosure provide a connector, a liquid cooling system, a cabinet, and a server. The connector includes a rotating member, a base, and a connection pipe. The rotating member includes a limiting through hole. The base includes a limiting groove, a first through hole, and a second through hole that are each provided around a first axis. The first through hole is provided at one end of the limiting groove along the first axis and communicates with the limiting groove. The second through hole is provided at the other end of the limiting groove along the first axis and communicates with the limiting groove. The limiting groove surrounds the rotating member. An inner diameter of the first through hole and an inner diameter of the second through hole at a position connected to the limiting groove are smaller than an outer diameter of the rotating member, and the base may limit the rotating member in the limiting groove and allow the rotating member to rotate relative to the limiting groove about the first axis and an axis perpendicular to the first axis. The connection pipe passes through the limiting through hole, the first through hole, and the second through hole and is connected to the rotating member. The connection pipe may move with the rotating member relative to the base. With this arrangement, when there is a system-level tolerance, the connection pipe may be deflected with the rotating member relative to the base, thereby accurately connecting to an auxiliary connector in the liquid cooling system. In addition, the connection pipe rotates with the rotating member, so that a lateral fitting stress caused by alignment deviation between the connectors may be eliminated or reduced, thereby improving the reliability of the liquid cooling system in a mating process and the sealing performance of the liquid cooling system during operation. The principle of the present disclosure is described in detail below with reference to FIG. 1 to FIG. 11.

In the present disclosure, a first direction X, a second direction Y, and a third direction Z refer to three spatial directions perpendicular to each other, which may correspond to three coordinate axes in a Cartesian coordinate system. For example, the first direction X is a horizontal direction, the second direction Y is a vertical direction, and the third direction Z is a longitudinal direction. It should be noted that the three directions are not limited to the Cartesian coordinate system, and may also be applied to other types of coordinate systems. Herein, the Cartesian coordinate system is used as an example to describe the structure of the connector 100 and the working principle of the connector 100 in detail.

As shown in FIG. 1 to FIG. 5, the connector 100 includes a rotating member 10, a base 20, and a connection pipe 30. The rotating member 10 is provided with a limiting through hole 13. The limiting through hole 13 may be used for limiting the connection pipe 30, so that the connection pipe 30 moves with the rotating member 10. As an example, the rotating member 10 may include an intermediate section of a sphere. An outer wall surface of the rotating member 10 may include at least a partial spherical structure. When the rotating member 10 is installed in the base 20, the rotating member 10 may rotate in multiple degrees of freedom relative to the base 20. In some embodiments, the limiting through hole 13 may be provided at a center of the rotating member 10, so that a central axis of the connection pipe 30 is aligned with the center of the rotating member 10. When the rotating member 10 rotates, the central axis of the limiting through hole 13 may be deflected by a certain angle with the rotating member 10.

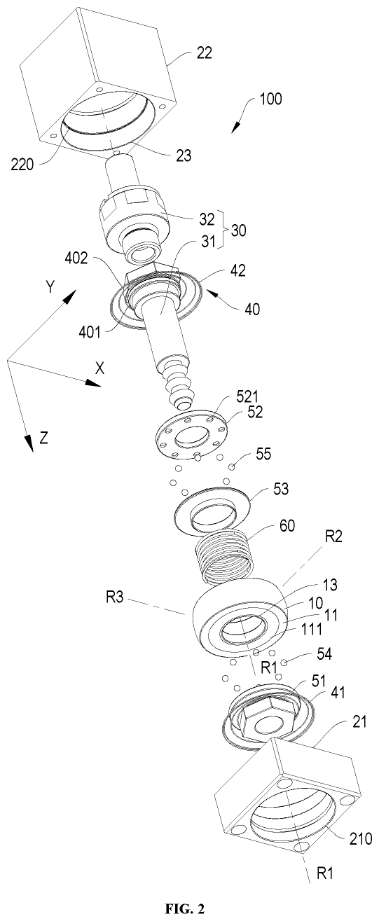

As shown in FIG. 2 to FIG. 5, the base 20 includes a limiting groove 23, a first through hole 210, and a second through hole 220 that are each provided around a first axis R1. The first through hole 210 is provided at one end of the limiting groove 23 along the first axis R1 and communicates with the limiting groove 23. The second through hole 220 is provided at the other end of the limiting groove 23 along the first axis R1 and communicates with the limiting groove 23. The rotating member 10 may be installed in the limiting groove 23 of the base 20 and at least partially surrounded by the limiting groove 23. An inner diameter of the first through hole 210 and an inner diameter of the second through hole 220 are smaller than an inner diameter of the limiting groove 23. To enable the rotating member 10 to rotate stably in the limiting groove 23, an outer diameter of the rotating member 10 may be equal to or slightly smaller than the inner diameter of the limiting groove 23. In this way, when the rotating member 10 rotates, the rotating member 10 does not shake relative to the base 20. The inner diameter of the first through hole 210 and the inner diameter of the second through hole 220 at the position connected to the limiting groove 23 are smaller than the outer diameter of the rotating member 10. The base 20 may limit the rotating member 10 in the limiting groove 23. In this way, the base 20 can allow the rotating member 10 to rotate in multiple directions relative to the limiting groove 23.

As shown in FIG. 1 to FIG. 5, the rotating member 10 may not only rotate about the first axis R1, but also deflect or swing about a second axis R2 and a third axis R3 that are perpendicular to the first axis R1. The first axis R1, the second axis R2, and the third axis R3 are perpendicular to each other in space. In this way, the rotating member 10 may rotate in the base 20 about three mutually perpendicular axes, thereby enabling the rotating member 10 to rotate in multiple directions spatially.

In some embodiments, as shown in FIG. 1 to FIG. 5, the base 20 and the rotating member 10 may form a ball hinge structure. For example, the base 20 is a ball socket of the ball hinge. An inner surface of the base 20 is a spherical groove, and the spherical groove fits with a spherical outer wall of the rotating member 10. With this arrangement, the ball hinge structure may enable the rotating member 10 to rotate in multiple directions.

As an example, the base 20 may be an integrally formed structure. The limiting groove 23 is recessed inward on one side of the base 20. In addition, a limiting ring (such as a snap ring or a pressure ring) may be provided at an opening of the limiting groove 23. In this way, the limiting ring may limit the rotating member 10 in the limiting groove 23, thereby preventing the rotating member 10 from being separated from the base 20 along the opening of the limiting groove 23.

As another example, as shown in FIG. 1 to FIG. 5, the base 20 may also adopt a split structure. For example, the base 20 includes a left half and a right half. The left half and the right half may be connected by a thread, a buckle, or a fastener. After the left and right halves are fixed together, the limiting groove 23 may be formed, and the rotating member 10 may be limited in the limiting groove 23.

As yet another example, the base 20 may further include a left half, a right half, and a limiting ring. The limiting ring surrounds the rotating member 10 in a circumferential direction, and may constrain a displacement of the rotating member 10 in a radial direction perpendicular to the first axis R1. The left half and the right half are arranged side by side on opposite sides of the limiting ring in a direction along the first axis R1. The left half and the right half may be fixed to the limiting ring by a connecting structure such as a bolt, thereby preventing the rotating member 10 from being separated from the limiting ring in the direction along the first axis R1.

It should be understood that the form of the base 20 mentioned above and elsewhere in the present disclosure is illustrative and is not intended to limit the scope of the present disclosure in any way. Any other suitable form of the base 20 is also possible.

As shown in FIG. 2 to FIG. 5, the connection pipe 30 passes through the limiting through hole 13, the first through hole 210, and the second through hole 220 and is connected to the rotating member 10. When the rotating member 10 rotates or deflects relative to the base 20, the connection pipe 30 may rotate with the rotating member 10 relative to the base 20.

With this arrangement, when there is a system-level tolerance, the connection pipe 30 may be deflected with the rotating member 10 relative to the base 20, thereby accurately connecting to the auxiliary connector 803 in the liquid cooling system. In addition, the connection pipe 30 rotates with the rotating member 10, so that the lateral fitting stress caused by the alignment deviation of the connector 100 may be eliminated or reduced, thereby improving the reliability of the liquid cooling system in the mating process and the sealing performance of the liquid cooling system during operation.

In some embodiments, as shown in FIG. 1 to FIG. 5, the base 20 includes a first portion 21 and a second portion 22. The first portion 21 and the second portion 22 are coupled to each other. The limiting groove 23 is formed between ends of the first portion 21 and the second portion 22 that are close to each other. The first through hole 210 is provided in the first portion 21. The second through hole 220 is provided in the second portion 22. With this arrangement, when the first portion 21 and the second portion 22 are connected, the first through hole 210 and the second through hole 220 communicate with the limiting groove 23, thereby enabling the connection pipe 30 to pass through the entire base 20 and be connected to the rotating member 10.

In some embodiments, as shown in FIG. 2 to FIG. 5, the connector 100 further includes a conical spring assembly 40. The conical spring assembly 40 is arranged coaxially with the connection pipe 30. The conical spring assembly 40 includes an inner connecting portion 401 and an outer connecting portion 402 that are spaced apart in a radial direction perpendicular to a central axis of the connection pipe 30. The inner connecting portion 401 is connected to the connection pipe 30, and the outer connecting portion 402 is connected to at least one of the first portion 21 or the second portion 22. The conical spring assembly 40 may apply, to the connection pipe 30, a force that aligns the central axis of the connection pipe 30 with the first axis R1. With this arrangement, before the connector 100 is connected to the auxiliary connector 803 of the liquid cooling system, the conical spring assembly 40 may use an elastic restoring force to adjust a position of the connection pipe 30, so that the central axis of the connection pipe 30 is aligned with the first axis R1. The conical spring assembly 40 may achieve a blind-mating floating connection between the connector 100 and the auxiliary connector 803, which helps to improve the assembly efficiency of the liquid cooling system.

In some embodiments, as shown in FIG. 2 to FIG. 5, the conical spring assembly 40 includes a first conical spring 41 and a second conical spring 42. An outer connecting portion 402 of the first conical spring 41 is connected to the first portion 21, and an inner connecting portion 401 of the first conical spring 41 is connected to the connection pipe 30. An outer connecting portion 402 of the second conical spring 42 is connected to the second portion 22, and an inner connecting portion 401 of the second conical spring 42 is connected to the connection pipe 30. When the connection pipe 30 is deflected or displaced during the mating process, the conical spring on one side may be compressed, and the conical spring on the other side may be stretched. The first conical spring 41 and the second conical spring 42 may make the central axis of the connection pipe 30 coincident with the first axis R1, thereby achieving the blind-mating floating connection between the connector 100 and the auxiliary connector 803.

In some embodiments, as shown in FIG. 2 to FIG. 5, an outer diameter of the connection pipe 30 is smaller than an inner diameter of the limiting through hole 13. In this way, in addition to being deflected with the rotating member 10, the connection pipe 30 may also float in multiple directions, thereby reducing the correction scratch and the lateral force in the insertion guiding process.

First, the connection pipe 30 may move in the limiting through hole 13 along an axial direction of the limiting through hole 13. When the connection pipe 30 of the connector 100 is connected to the auxiliary connector 803 of the liquid cooling system, the connection pipe 30 may move along a third direction Z. As an example, during the mating process, the conical spring assembly 40 may apply an elastic force to the connection pipe 30 along the third direction Z, that is, provide a pre-pressure to the connection pipe 30, thereby ensuring the close contact between the connection pipe 30 and the auxiliary connector 803, and helping to improve the sealing performance between the connection pipe 30 and the auxiliary connector 803.

Second, the connection pipe 30 may also rotate and float about the first axis R1 by a certain angle, for example, ±2°. In this way, the connector 100 has an adaptive capability, thereby improving the success rate and reliability of the mating.

In addition, when there is a positional deviation between the connection pipe 30 and the auxiliary connector 803 along a first direction X and a second direction Y, the connection pipe 30 may move in the limiting through hole 13 along the first direction X and the second direction Y under the elastic support of the conical spring assembly 40. For example, the connection pipe 30 may float by ±2.5 mm in the first direction X and the second direction Y. In this way, when there is a position error in the first direction X and the second direction Y during the mating process, the connection pipe 30 may also be connected to the auxiliary connector 803, thereby reducing the influence of the correction scratch and the lateral force in the insertion guiding process.

It may be learned that the connection pipe 30 may not only be deflected with the rotating member 10 in the base 20, but also rotate and float about the first axis R1, and may also float in the first direction X, the second direction Y, and the third direction Z. In this way, the difficulty in correcting the connector 100 in the insertion guiding process may be reduced, unnecessary friction and lateral force may be reduced, and the smoothness and sealing performance of the entire connection process may be improved.

In some embodiments, as shown in FIG. 2 to FIG. 5, the rotating member 10 further includes a first bearing surface 11 and a second bearing surface 12 that are provided at opposite ends in an axial direction of the limiting through hole 13. The connector 100 further includes a first support ring 51, a second support ring 52, and a third support ring 53. The first support ring 51 is arranged adjacent to the first bearing surface 11 and coaxially with the connection pipe 30. The first support ring 51 is connected to the connection pipe 30 and slidably connected to the first bearing surface 11. As an example, the connection pipe 30 includes a first annular protrusion provided on a circumferential side wall, and the first annular protrusion may limit the first support ring 51. The second support ring 52 is arranged adjacent to the second bearing surface 12 and coaxially with the connection pipe 30. The second support ring 52 is connected to the connection pipe 30. The third support ring 53 is arranged coaxially with the connection pipe 30 and between the second bearing surface 12 and the second support ring 52. The third support ring 53 is connected to the rotating member 10 and slidably connected to the second support ring 52. As an example, the connection pipe 30 further includes a second annular protrusion provided on the circumferential side wall, and the second annular protrusion may limit the first support ring 51.

With this arrangement, the first support ring 51 and the second support ring 52 may enable the connection pipe 30 to move smoothly in the first direction X and the second direction Y, and allow the connection pipe 30 to rotate and float about the first axis R1 by a certain angle, thereby reducing the influence of the correction scratch and the lateral force in the insertion guiding process.

In some embodiments, as shown in FIG. 2 to FIG. 5, the first support ring 51 includes a plurality of first grooves 511 provided on a side facing the first bearing surface 11. The plurality of first grooves 511 are evenly arranged around the central axis of the connection pipe 30. The second support ring 52 includes a plurality of second grooves 521 provided on a side facing the third support ring 53. The plurality of second grooves 521 are evenly arranged around the central axis of the connection pipe 30. The connector 100 further includes a plurality of first balls 54 and a plurality of second balls 55. The plurality of first balls 54 are respectively arranged in corresponding first grooves 511 of the plurality of first grooves 511. Each first ball 54 protrudes out of the corresponding first groove 511 and is in contact with the first bearing surface 11. The plurality of second balls 55 are respectively arranged in corresponding second grooves 521 of the plurality of second grooves 521. Each second ball 55 protrudes out of the corresponding second groove 521 and is in contact with the third support ring 53.

In this way, when the connection pipe 30 floats in the first direction X and the second direction Y or the connection pipe 30 rotates and floats about the first axis R1, the plurality of first balls 54 may roll on the first bearing surface 11, thereby reducing the friction between the first support ring 51 and the first bearing surface 11. The plurality of second balls 55 may roll on a side of the third support ring 53 facing the second support ring 52, thereby reducing the friction between the second support ring 52 and the third support ring 53.

In some embodiments, as shown in FIG. 2 to FIG. 5, the first bearing surface 11 includes a first annular limiting groove 111 provided around the central axis of the connection pipe 30. The plurality of first balls 54 may roll in a circumferential direction of the first annular limiting groove 111. The side of the third support ring 53 facing the second support ring 52 includes a second annular limiting groove 531 provided around the central axis of the connection pipe 30. The plurality of second balls 55 may roll in a circumferential direction of the second annular limiting groove 531.

In this way, when the connection pipe 30 rotates about the first axis R1, the plurality of first balls 54 roll in the first annular limiting groove 111 and in the circumferential direction of the first annular limiting groove 111. The plurality of second balls 55 roll in the second annular limiting groove 531 and in the circumferential direction of the second annular limiting groove 531. The first annular limiting groove 111 may limit the plurality of first balls 54, and the second annular limiting groove 531 may limit the plurality of second balls 55.

In some embodiments, as shown in FIG. 2 to FIG. 5, centers of the plurality of first balls 54 may be located on a first circle, and centers of the plurality of second balls 55 may be located on a second circle. A diameter of the first circle is greater than an inner diameter of the first annular limiting groove 111 and smaller than an outer diameter of the first annular limiting groove 111. A diameter of the second circle is greater than an inner diameter of the second annular limiting groove 531 and smaller than an outer diameter of the second annular limiting groove 531. In this way, the plurality of first balls 54 may roll in a radial direction of the first annular limiting groove 111, and the plurality of second balls 55 may roll in a radial direction of the second annular limiting groove 531, thereby enabling the connection pipe 30 to float in the first direction X and the second direction Y.

In some embodiments, as shown in FIG. 2 to FIG. 5, a distance between the second bearing surface 12 and the second support ring 52 in the axial direction of the connection pipe 30 is greater than a width of the third support ring 53 in the axial direction of the connection pipe 30, thereby allowing the connection pipe 30 to move in the axial direction thereof. The connector 100 further includes an elastic assembly 60. The elastic assembly 60 is connected to the rotating member 10 and the third support ring 53. The elastic assembly 60 may apply, to the third support ring 53, a force that presses the third support ring 53 against the plurality of second balls 55. In this way, under the action of the elastic force of the elastic assembly 60, the third support ring 53 is kept in contact with the second balls 55. When the connection pipe 30 is connected to the auxiliary connector 803, the connection pipe 30 has a certain floating amount in the third direction Z, and at the same time, the elastic assembly 60 applies a pre-pressure to the connection pipe 30, so that the connection pipe 30 may be in close contact with the auxiliary connector 803, thereby improving the sealing performance therebetween.

In some embodiments, as shown in FIG. 2 to FIG. 5, the elastic assembly 60 may include a single spring coaxially arranged with the connection pipe 30. An inner diameter of the single spring is greater than an outer diameter of the connection pipe 30. The single spring may be arranged around an outer circumference of the connection pipe 30. One end of the single spring is connected to the rotating member 10, and the other end of the single spring is connected to the third support ring 53. In the assembled state, the spring is in a pre-compressed state, thereby applying an axial force to the third support ring 53 along the connection pipe 30, and pressing the third support ring 53 against the plurality of second balls 55. With this arrangement, the single spring not only enables the stable contact between the third support ring 53 and the second balls 55, but also provides a pre-pressure for the axial floating of the connection pipe 30 in the third direction Z, thereby achieving the close contact and sealing with the auxiliary connector 803.

In other embodiments, the elastic assembly 60 may further include a plurality of sub-springs evenly arranged in a circumferential direction of the connection pipe 30. One end of each sub-spring is connected to the rotating member 10, and the other end of each sub-spring is connected to the third support ring 53. With this arrangement, the plurality of sub-springs not only enable the stable contact between the third support ring 53 and the second balls 55, but also provide a pre-pressure for the axial floating of the connection pipe 30 in the third direction Z, thereby achieving the close contact and sealing with the auxiliary connector 803.

In some embodiments, as shown in FIG. 2 to FIG. 5, the connection pipe 30 includes a pipe body 31 and a quick connector 32. The pipe body 31 passes through the limiting through hole 13 in the rotating member 10 and the first through hole 210 in the base 20 and is fixedly connected to the rotating member 10. The quick connector 32 is arranged at an axial end of the pipe body 31 and communicates with the pipe body 31. The quick connector 32 passes through the second through hole 220 and extends to an exterior of the base 20, to be connected to the auxiliary connector 803 of the liquid cooling system. In this way, when the connector 100 is connected to the auxiliary connector 803 of the liquid cooling system, the quick connector 32 may be quickly plugged into and unplugged from the auxiliary connector 803, thereby improving the efficiency of installing and disassembling the liquid cooling system. In addition, the quick connector may also maintain a good sealing performance with the auxiliary connector 803, thereby preventing the cooling medium from leaking.

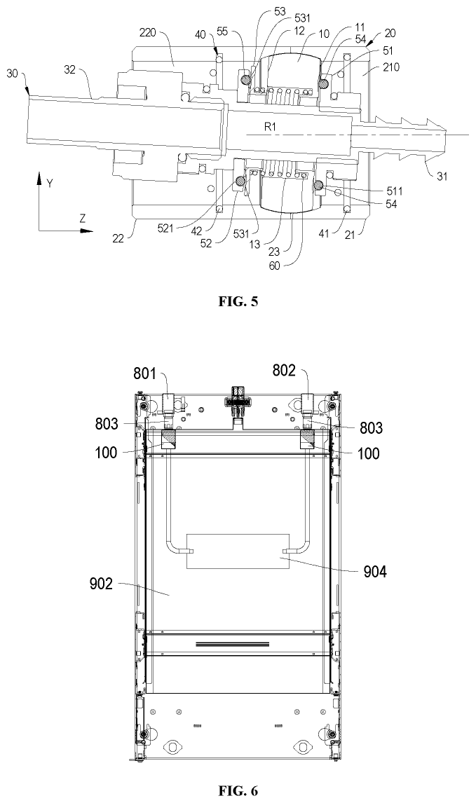

The present disclosure further provides a liquid cooling system. As shown in FIG. 6 to FIG. 11, the liquid cooling system includes a liquid inlet pipe 801, a liquid outlet pipe 802, a pair of auxiliary connectors 803, a heat exchange unit 804, and any one of the foregoing connectors 100. The pair of auxiliary connectors 803 respectively communicate with the liquid inlet pipe 801 and the liquid outlet pipe 802. The heat exchange unit 804 includes an inlet and an outlet. The pair of connectors 100 respectively communicate with the inlet and the outlet of the heat exchange unit 804, and are respectively detachably connected to a corresponding auxiliary connector 803 of the pair of auxiliary connectors 803.

During the heat exchange process, the cooling medium flows from an external pipeline into the liquid inlet pipe 801, passes through a liquid inlet-side connector of the pair of auxiliary connectors 803, and then enters the inlet of the heat exchange unit 804 via a corresponding connector 100. The temperature of the cooling medium rises after absorbing heat at the heat exchange unit 804, and then the cooling medium flows out of the outlet of the heat exchange unit 804. The cooling medium is connected to the liquid outlet-side auxiliary connector 803 via another connector 100, then enters the liquid outlet pipe 802, and finally returns to an external cooling device for cooling.

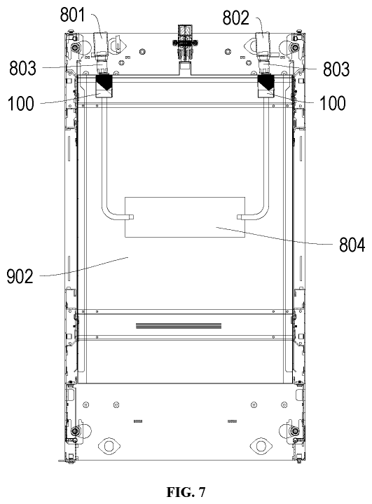

When there is a system-level tolerance, as shown in FIG. 7, the connection pipe 30 may be deflected with the rotating member 10 relative to the base 20, thereby accurately connecting to the auxiliary connector 803 in the liquid cooling system. In addition, the connection pipe 30 rotates with the rotating member 10, so that the lateral fitting stress caused by the alignment deviation between the connectors 100 may be eliminated or reduced, thereby improving the reliability of the liquid cooling system in the mating process and the sealing performance of the liquid cooling system during operation.

In some embodiments, as shown in FIG. 6 and FIG. 7, the heat exchange unit 804 may include a cold plate. In this way, the cooling medium may flow from the liquid inlet pipe 801 into the cold plate via the connector 100, and after absorbing heat of a heat-generating component, the cooling medium flows from an outlet of the cold plate into the liquid outlet pipe 802 via another connector 100, and returns to the external cooling device for cooling.

The present disclosure further provides a cabinet. As shown in FIG. 7 to FIG. 11, the cabinet includes a cabinet body 901, a support member 902, and any one of the foregoing liquid cooling systems. The support member 902 is detachably connected to the cabinet body 901. The liquid inlet pipe 801, the liquid outlet pipe 802, and the pair of auxiliary connectors 803 are arranged in the cabinet body 901, and the heat exchange unit 804 and the pair of connectors 100 are connected to the support member 902. With this arrangement, an operator may mount a heat-generating unit such as a graphics card on the support member 902 and bring the heat-generating unit into contact with the heat exchange unit 804. Subsequently, the support member 902 is pushed into the cabinet body 901, so that the connector 100 is connected to the auxiliary connector 803 in the cabinet body 901, thereby communicating the liquid cooling circuit. Heat generated by the heat-generating unit during operation is transferred to the cooling medium by the heat exchange unit 804, and taken away by the circulating cooling medium, thereby achieving efficient heat dissipation. The support member 902 is detachably connected to the cabinet body 901, which facilitates the installation, maintenance, and replacement of the heat-generating unit.

When there is a system-level tolerance, as shown in FIG. 7, the connection pipe 30 may be deflected with the rotating member 10 relative to the base 20, thereby accurately connecting to the auxiliary connector 803 in the liquid cooling system. In addition, the connection pipe 30 rotates with the rotating member 10, so that the lateral fitting stress caused by the alignment deviation between the connectors 100 may be eliminated or reduced, thereby improving the reliability of the liquid cooling system in the mating process and the sealing performance of the liquid cooling system during operation.

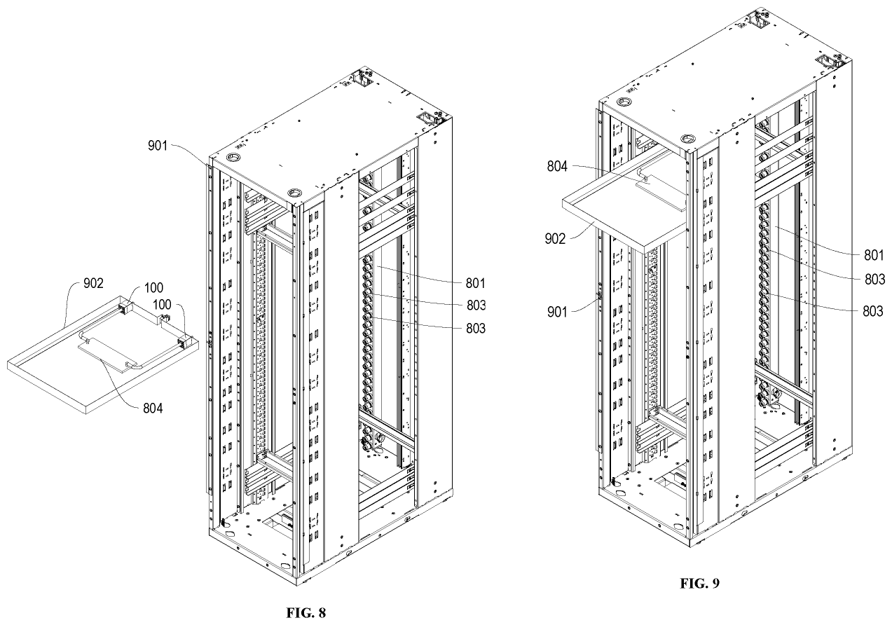

In some embodiments, as shown in FIG. 8 to FIG. 11, the liquid inlet pipe 801 and the liquid outlet pipe 802 may be arranged in a vertical direction. The liquid inlet pipe 801 and the liquid outlet pipe 802 are each provided with a plurality of auxiliary connectors 803. After a plurality of support members 902 are inserted into the cabinet body 901, the connector 100 mounted on the support member 902 may be connected to a corresponding auxiliary connector 803, thereby achieving the communication of the cooling circulation circuit. In this way, a plurality of heat exchange units 804 and a plurality of heat-generating components may be arranged in the cabinet body 901, thereby achieving a high-density arrangement and efficient heat dissipation of functional components.

The present disclosure further provides a server. The server includes any one of the foregoing cabinets and a functional unit. One or more functional units may be mounted on each support member 902. As an example, the functional unit may include at least one of a processing unit, a storage unit, a network unit, a power unit, an expansion unit, an input/output unit, and a security unit. The functional unit abuts against the heat exchange unit 804 on the support member 902. When the server is running, the heat generated by the functional unit may be exchanged with the heat exchange unit 804, so that the temperature of the functional unit may be kept stable, and the performance of the functional unit is prevented from being affected by an excessively high temperature.

Embodiments of the present disclosure are further reflected in the following examples.

Example 1. A connector, including:
a rotating member, including a limiting through hole;
a base, including a limiting groove, a first through hole, and a second through hole that are respectively provided around a first axis, the first through hole being provided at one end of the limiting groove along the first axis and communicating with the limiting groove, the second through hole being provided at the other end of the limiting groove along the first axis and communicating with the limiting groove, the limiting groove surrounding the rotating member, and an inner diameter of the first through hole and an inner diameter of the second through hole at a position connected to the limiting groove being smaller than an outer diameter of the rotating member, to limit the rotating member in the limiting groove and allow the rotating member to rotate relative to the limiting groove about the first axis and an axis perpendicular to the first axis; and
a connection pipe, passing through the limiting through hole, the first through hole, and the second through hole and being connected to the rotating member, to move with the rotating member relative to the base.

Example 2. The connector of Example 1, where the base includes:
a first portion and a second portion that are coupled to each other, the limiting groove being formed between ends of the first portion and the second portion that are close to each other, the first through hole being provided in the first portion, and the second through hole being provided in the second portion.

Example 3. The connector of Example 2, further including:
a conical spring assembly, coaxially arranged with the connection pipe and including an inner connecting portion and an outer connecting portion that are spaced apart in a radial direction perpendicular to a central axis of the connection pipe, the inner connecting portion being connected to the connection pipe, and the outer connecting portion being connected to at least one of the first portion or the second portion, to apply, to the connection pipe, a force that aligns the central axis of the connection pipe with the first axis.

Example 4. The connector of Example 3, where the conical spring assembly includes:
a first conical spring, having an outer connecting portion connected to the first portion and an inner connecting portion connected to the connection pipe; and
a second conical spring, having an outer connecting portion connected to the second portion and an inner connecting portion connected to the connection pipe.

Example 5. The connector of Example 4, where an outer diameter of the connection pipe is smaller than an inner diameter of the limiting through hole, to allow the connection pipe to move in the limiting through hole in an axial direction of the limiting through hole.

Example 6. The connector of Example 5, where the rotating member further includes a first bearing surface and a second bearing surface that are provided at opposite ends in the axial direction of the limiting through hole, and the connector further includes:
a first support ring, arranged adjacent to the first bearing surface and coaxially with the connection pipe, the first support ring being connected to the connection pipe and slidably connected to the first bearing surface;
a second support ring, arranged adjacent to the second bearing surface and coaxially with the connection pipe, the second support ring being connected to the connection pipe; and
a third support ring, arranged coaxially with the connection pipe and between the second bearing surface and the second support ring, the third support ring being connected to the rotating member and slidably connected to the second support ring.

Example 7. The connector of Example 6, where the first support ring includes a plurality of first grooves provided on a side facing the first bearing surface, the plurality of first grooves being evenly arranged around the central axis of the connection pipe, the second support ring includes a plurality of second grooves provided on a side facing the third support ring, the plurality of second grooves being evenly arranged around the central axis of the connection pipe, and the connector further includes:
a plurality of first balls, respectively arranged in corresponding first grooves of the plurality of first grooves, each first ball protruding out of the corresponding first groove and being in contact with the first bearing surface; and
a plurality of second balls, respectively arranged in corresponding second grooves of the plurality of second grooves, each second ball protruding out of the corresponding second groove and being in contact with the third support ring.

Example 8. The connector of Example 7, where the first bearing surface includes a first annular limiting groove provided around the central axis of the connection pipe, and the plurality of first balls are adapted to roll at least in a circumferential direction of the first annular limiting groove; and/or
a side of the third support ring facing the second support ring includes a second annular limiting groove provided around the central axis of the connection pipe, and the plurality of second balls are adapted to roll at least in a circumferential direction of the second annular limiting groove.

Example 9. The connector of Example 7 or 8, where a distance between the second bearing surface and the second support ring in the axial direction of the connection pipe is greater than a width of the third support ring in the axial direction of the connection pipe, to allow the connection pipe to move in the axial direction, and the connector further includes:
an elastic assembly, connected to the rotating member and the third support ring, to apply, to the third support ring, a force that presses the third support ring against the plurality of second balls.

Example 10. The connector of Example 9, where the elastic assembly includes a single spring coaxially arranged with the connection pipe.

Example 11. The connector of Example 9, where the elastic assembly includes a plurality of sub-springs evenly arranged in a circumferential direction of the connection pipe, one end of each sub-spring being connected to the rotating member and the other end of each sub-spring being connected to the third support ring.

Example 12. The connector of any one of Examples 1 to 8, 10, and 11, where the connection pipe includes:
a pipe body, passing through the limiting through hole and the first through hole and being connected to the rotating member; and
a quick connector, arranged at an axial end of the pipe body and communicating with the pipe body, the quick connector passing through the second through hole and extending to an exterior of the base, to be connected to an auxiliary connector of a liquid cooling system.

Example 13. A liquid cooling system, including:
a liquid inlet pipe;
a liquid outlet pipe;
a pair of auxiliary connectors, respectively communicating with the liquid inlet pipe and the liquid outlet pipe;
a heat exchange unit, including an inlet and an outlet; and
a pair of connectors of any one of Examples 1 to 12, respectively communicating with the inlet and the outlet of the heat exchange unit, and respectively detachably connected to a corresponding auxiliary connector of the pair of auxiliary connectors.

Example 14. The liquid cooling system of Example 13, where the heat exchange unit includes a cold plate.

Example 15. A cabinet, including:
a cabinet body;
a support member, detachably connected to the cabinet body; and
the liquid cooling system of Example 13 or 14, the liquid inlet pipe, the liquid outlet pipe, and the pair of auxiliary connectors being arranged in the cabinet body, and the heat exchange unit and the pair of connectors being connected to the support member.

Example 16. A server, including:
the cabinet of Example 15.

The embodiments of the present disclosure have been described above. The foregoing description is illustrative, non-exhaustive, and is not limited to the disclosed embodiments. Many modifications and variations are obvious to those of ordinary skill in the art without departing from the scope and spirit of the described embodiments. The selection of terms used herein is intended to best explain the principles, practical applications, or technical improvements to the market of the embodiments, or to enable other people of ordinary skill in the art to understand the embodiments disclosed herein.

1. A connector, comprising:
a rotating member, comprising a limiting through hole;
a base, the base comprising a limiting groove, a first through hole, and a second through hole that are provided around a first axis, respectively, the first through hole being provided at one end of the limiting groove along the first axis and communicating with the limiting groove, the second through hole being provided at the other end of the limiting groove along the first axis and communicating with the limiting groove, the limiting groove surrounding the rotating member, and an inner diameter of the first through hole and an inner diameter of the second through hole at a position connected to the limiting groove being smaller than an outer diameter of the rotating member, to limit the rotating member in the limiting groove and allow the rotating member to rotate relative to the limiting groove about the first axis and an axis perpendicular to the first axis; and
a connection pipe, passing through the limiting through hole, the first through hole, and the second through hole and being connected to the rotating member, to move with the rotating member relative to the base.

2. The connector of claim 1, wherein the base comprises:
a first portion and a second portion that are coupled to each other, wherein the limiting groove is formed between ends of the first portion and the second portion that are close to each other, the first through hole is provided in the first portion, and the second through hole is provided in the second portion.

3. The connector of claim 2, further comprising:
a conical spring assembly, coaxially arranged with the connection pipe and comprising an inner connecting portion and an outer connecting portion that are spaced apart in a radial direction perpendicular to a central axis of the connection pipe, the inner connecting portion being connected to the connection pipe, and the outer connecting portion being connected to at least one of the first portion or the second portion, to apply, to the connection pipe, a force that aligns the central axis of the connection pipe with the first axis.

4. The connector of claim 3, wherein the conical spring assembly comprises:
a first conical spring, having an outer connecting portion connected to the first portion and an inner connecting portion connected to the connection pipe; and
a second conical spring, having an outer connecting portion connected to the second portion and an inner connecting portion connected to the connection pipe.

5. The connector of claim 4, wherein an outer diameter of the connection pipe is smaller than an inner diameter of the limiting through hole, to allow the connection pipe to move in the limiting through hole in an axial direction of the limiting through hole.

6. The connector of claim 5, wherein the rotating member further comprises a first bearing surface and a second bearing surface that are provided at opposite ends in the axial direction of the limiting through hole, and the connector further comprises:
a first support ring, arranged adjacent to the first bearing surface and coaxially with the connection pipe, the first support ring being connected to the connection pipe and slidably connected to the first bearing surface;
a second support ring, arranged adjacent to the second bearing surface and coaxially with the connection pipe, the second support ring being connected to the connection pipe; and
a third support ring, arranged coaxially with the connection pipe and between the second bearing surface and the second support ring, the third support ring being connected to the rotating member and slidably connected to the second support ring.

7. The connector of claim 6, wherein the first support ring comprises a plurality of first grooves provided on a side facing the first bearing surface, the plurality of first grooves being evenly arranged around the central axis of the connection pipe, the second support ring comprises a plurality of second grooves provided on a side facing the third support ring, the plurality of second grooves being evenly arranged around the central axis of the connection pipe, and the connector further comprises:
a plurality of first balls, respectively arranged in corresponding first grooves of the plurality of first grooves, each first ball protruding out of the corresponding first groove and being in contact with the first bearing surface; and
a plurality of second balls, respectively arranged in corresponding second grooves of the plurality of second grooves, each second ball protruding out of the corresponding second groove and being in contact with the third support ring.

8. The connector of claim 7, wherein the first bearing surface comprises a first annular limiting groove provided around the central axis of the connection pipe, and the plurality of first balls are adapted to roll at least in a circumferential direction of the first annular limiting groove; and/or
a side of the third support ring facing the second support ring comprises a second annular limiting groove provided around the central axis of the connection pipe, and the plurality of second balls are adapted to roll at least in a circumferential direction of the second annular limiting groove.

9. The connector of claim 7, wherein a distance between the second bearing surface and the second support ring in the axial direction of the connection pipe is greater than a width of the third support ring in the axial direction of the connection pipe, to allow the connection pipe to move in the axial direction, and the connector further comprises:
an elastic assembly, connected to the rotating member and the third support ring, to apply, to the third support ring, a force that presses the third support ring against the plurality of second balls.

10. The connector of claim 9, wherein the elastic assembly comprises a single spring coaxially arranged with the connection pipe.

11. The connector of claim 9, wherein the elastic assembly comprises a plurality of sub-springs evenly arranged in a circumferential direction of the connection pipe, one end of each sub-spring being connected to the rotating member and the other end of each sub-spring being connected to the third support ring.

12. The connector of claim 1, wherein the connection pipe comprises:
a pipe body, passing through the limiting through hole and the first through hole and being connected to the rotating member; and
a quick connector, arranged at an axial end of the pipe body and communicating with the pipe body, the quick connector passing through the second through hole and extending to an exterior of the base, to be connected to an auxiliary connector of a liquid cooling system.

13. A liquid cooling system, comprising:
a liquid inlet pipe;
a liquid outlet pipe;
a pair of auxiliary connectors, respectively communicating with the liquid inlet pipe and the liquid outlet pipe;
a heat exchange unit, comprising an inlet and an outlet; and
a pair of connectors, respectively communicating with the inlet and the outlet of the heat exchange unit, and respectively detachably connected to a corresponding auxiliary connector of the pair of auxiliary connectors, wherein each of the pair of connectors comprises:
a rotating member, comprising a limiting through hole;
a base, the base comprising a limiting groove, a first through hole, and a second through hole that are provided around a first axis, respectively, the first through hole being provided at one end of the limiting groove along the first axis and communicating with the limiting groove, the second through hole being provided at the other end of the limiting groove along the first axis and communicating with the limiting groove, the limiting groove surrounding the rotating member, and an inner diameter of the first through hole and an inner diameter of the second through hole at a position connected to the limiting groove being smaller than an outer diameter of the rotating member, to limit the rotating member in the limiting groove and allow the rotating member to rotate relative to the limiting groove about the first axis and an axis perpendicular to the first axis; and
a connection pipe, passing through the limiting through hole, the first through hole, and the second through hole and being connected to the rotating member, to move with the rotating member relative to the base.

14. The liquid cooling system of claim 13, wherein the heat exchange unit comprises a cold plate.

15. The liquid cooling system of claim 13, wherein the base comprises:
a first portion and a second portion that are coupled to each other, wherein the limiting groove is formed between ends of the first portion and the second portion that are close to each other, the first through hole is provided in the first portion, and the second through hole is provided in the second portion.

16. The liquid cooling system of claim 15, wherein each of the pair of connectors further comprises:
a conical spring assembly, coaxially arranged with the connection pipe and comprising an inner connecting portion and an outer connecting portion that are spaced apart in a radial direction perpendicular to a central axis of the connection pipe, the inner connecting portion being connected to the connection pipe, and the outer connecting portion being connected to at least one of the first portion or the second portion, to apply, to the connection pipe, a force that aligns the central axis of the connection pipe with the first axis.

17. The liquid cooling system of claim 16, wherein the conical spring assembly comprises:
a first conical spring, having an outer connecting portion connected to the first portion and an inner connecting portion connected to the connection pipe; and
a second conical spring, having an outer connecting portion connected to the second portion and an inner connecting portion connected to the connection pipe.

18. The liquid cooling system of claim 13, wherein the connection pipe comprises:
a pipe body, passing through the limiting through hole and the first through hole and being connected to the rotating member; and
a quick connector, arranged at an axial end of the pipe body and communicating with the pipe body, the quick connector passing through the second through hole and extending to an exterior of the base, to be connected to an auxiliary connector of a liquid cooling system.

19. A cabinet, comprising:
a cabinet body;
a support member, detachably connected to the cabinet body; and
the liquid cooling system of claim 13, the liquid inlet pipe, the liquid outlet pipe, and the pair of auxiliary connectors being arranged in the cabinet body, and the heat exchange unit and the pair of connectors being connected to the support member.

20. A server, comprising:
the cabinet of claim 19.
